(19) United States
(12) Patent Application Publication
(10) Pub. No.: US 2014/0203254 A1
(43) Pub. Date: Jul. 24, 2014

(54) Organic Electronic Component

(71) Applicants: Sascha Dorok, Dresden (DE); Jan Blochwitz-Nimoth, Dresden (DE); Tobias Canzler, Dresden (DE); Hagen Klauk, Stuttgart (DE); Frederik Ante, Stuttgart (DE)

(72) Inventors: Sascha Dorok, Dresden (DE); Jan Blochwitz-Nimoth, Dresden (DE); Tobias Canzler, Dresden (DE); Hagen Klauk, Stuttgart (DE); Frederik Ante, Stuttgart (DE)

(73) Assignees: Max-Planck-Gesellschaft zur Foerderung der Wissenschaften e.V., Muenchen (DE); Novaled AG, Dresden (DE)

(21) Appl. No.: 14/127,142

(22) PCT Filed: Jun. 20, 2012
(86) PCT No.: PCT/EP2012/061783

§ 371 Date: Mar. 13, 2014

(30) Foreign Application Priority Data
Jun. 22, 2011 (EP) 11170946.5

(51) Int. Cl. H01L 51/05

(52) U.S. Cl. CPC H01L 51/0512
USPC 257/40

(57) ABSTRACT

The invention relates to an organic electron component having a first electrode, a second electrode, a channel layer comprising an organic semiconducting material and a dopant material.

### FIELD OF THE INVENTION

The invention relates to an organic electronic component.

### BACKGROUND OF THE INVENTION

Organic semiconductors have gained great attention in recent years because of their low cost, the possibility of depositing them on large surfaces and flexible substrates and the great selection of suitable molecules. Organic semiconductors may be used in switchable components, for example, such as transistors and in resistors.

Of the so-called planar components, the organic transistor is the most important component. Organic thin-film transistors (OTFTs) in particular have been investigated and developed for many years already. It is expected that OTFTs will be used on a large scale, for example, in inexpensive integrated circuits for non-contact detection marks (RFID), but also for display screen triggering (backplane). To permit inexpensive applications, thin-film processes are needed in general for manufacturing the transistors. In recent years performance features have been improved to the extent that the commercialization of organic transistors is foreseeable. For example, there have been reports of OTFTs of up to 6 cm2/Vs for electrons based on fullerene C60 and up to 5.5 cm2/Vs for holes based on pentacene.

OTFTs with an arrangement of additional layers on an active semiconductor layer have been described. The additional layers are also designated as encapsulation layers or cover layers. For example, double layers of pentacene and fullerene C60 have been used to achieve ambipolar component functionality (Wang et al., Org. Electron. 7, 457 (2006)). In this specific case, it can be deduced from the energy levels that there is not a technically relevant change in the charge carrier density in the active layer. The document US 2007/034860 A1 also describes such a structure.

The document U.S. Pat. No. 5,500,537 describes an OTFT structure in which another layer similar to the encapsulation layer is applied to an active layer. The active layer is a polymer layer. The additional layer controls the conductivity of the active layer. However, the proposed arrangement can function only in geometries of the layers in which source/drain contacts of the component are not arranged in direct contact with the additional layer because otherwise high OFF currents would be unavoidable.

The document US 2006/0202196 A1 describes structures having an encapsulation layer embodied as an electrically homogeneous doped layer wherein a matrix material of the encapsulation layer is the same as or similar to a material of an active layer. This means that the mobility of the active layer and the capsule layer and that of the capsule layer are the same or at least similar, and that the electric conductivity of the capsule layer is even greater than or at least equal to the electric conductivity of the active layer in the OFF state because of the electric doping.

Charge carrier transport in thin organic layers is described in general by thermally activated charge carrier hopping which leads to a relatively low mobility and a strong influence of disorder. The field mobility in OTFTs depends on the charge carrier density in general. a relatively high gate voltage is Therefore usually necessary to fill the localized states and to achieve a high charge carrier mobility in the organic layers.

In addition, the required applied voltage must be very high if charge carrier injection between an electrode and a semiconductor is not optimal. However, this is usually the case with interfaces between a metal and an organic material.

### BRIEF SUMMARY

The object of the invention is to create an improved organic electronic component which can be operated at a lower voltage.

This object is achieved according to the invention by a component according to the Independent Claim 1. Advantageous embodiments of the invention are the subject matter of the dependent claims.

The invention includes the idea of an organic electronic component having a first electrode, a second electrode, a channel layer which comprises an organic semiconducting material and a dopant material according to formula A-B (Formula (I)), wherein

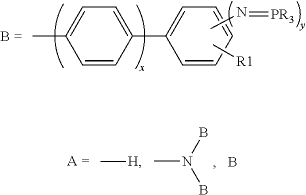

and where R1, R, x and y are selected independently for B from the following groups:

x is 0, 1 or 2,

y is 1, 2, 3 or 4,

R is selected from the aryl group and

R1 is from the alkyl group or the alkoxy group.

The components R1 and R as well as the indices x and y may be selected independently of each other for each B in the dopant material. For the case when A is the same as B, so the dopant material has formula B-B, the two Bs may have different definitions.

The channel layer comprises the channel, which is also known as the current channel or the conducting channel. The channel layer comprises an organic semiconducting material. The organic semiconductor material is a charge transport material for charge carriers, for example, holes or electrons. It may be formed as a matrix material. The term “matrix material” here means that the material constitutes most of the layer. The matrix material typically constitutes more than 50 vol % of the layer, preferably more than 90 vol %. It is preferably provided that the organic semiconducting material is an electron-transporting material.

The electrodes have a very high conductivity in comparison with the channel layer. For example, the electrodes may consist of the following group of materials: metal, conductive metal oxides, conductive polymer-based mixtures or mixtures thereof. The two electrodes are preferably free of mutual overlapping. The two electrodes do not have any direct contact with one another, for example.

In one embodiment of the invention, the component may be a resistor. The channel layer here determines most of the resistance value of the component.

In another embodiment of the invention, it is provided that the component is an overcurrent protection device (fuse). The switching capacity of the overcurrent protection device here is determined mainly by the channel layer, for example, its breakdown voltage, current and/or temperature.

In another embodiment of the invention, it is possible to provide that the component is a transducer, for example, a strain gauge. The channel layer here serves as a main semiconductor layer in the component. The conductivity of the component changes when there is a change in the properties of the organic semiconducting material in the channel layer due to external influences.

In another embodiment of the invention, it is possible to provide that the component is a transistor, for example, an organic thin-film transistor (OTFT) or an organic field effect transistor (OFET). In one embodiment the transistor may be a step-edge OFET. Conventional step-edge transistors are known from the prior art, for example, from Fanghua Pu et al. Applied Physics Express 4 (2011) 054203.

The transistor may comprise a first electrode, a second electrode and a gate electrode as well as multiple layers. The electrodes and the multiple layers of the transistor may be formed on a substrate, for example, e.g., as thin films. It may be provided that one or more electrodes are made available with the substrate, for example, by means of a silicon substrate. For example, a drain contact and a source contact, or alternatively, the gate electrode may be formed in or on the substrate. An organic field effect transistor of the n type is preferred.

In a preferred embodiment it is provided that the dopant material is incorporated into a doping material layer. Additionally or alternatively, it is possible to provide that the dopant material is incorporated into the organic semiconducting material.

In another refinement of the invention it is possible to provide that the doping material layer is made of the dopant material.

According to a preferred embodiment it is provided that the doping material layer is arranged on the organic semiconductor material.

According to a refinement of the invention, the amount of the difference between the oxidation potential of the dopant material (OP) and the reduction potential (RP) of the organic semiconducting material is greater than approximately 0.5 V. The absolute value of the difference between the OP and the RP is thus either less than −0.5 V or greater than 0.5 V.

According to another refinement, it is possible to provide that the doping material layer is formed in multiple layers. The doping material layer may comprise a first partial layer and a second partial layer, wherein the first partial layer is made of the dopant material, the second partial layer is made of a charge carrier transporting matrix material and the second partial layer is arranged between the first partial layer and the channel layer as well as being in contact with the first partial layer and the channel layer.

According to another preferred embodiment, it is provided that the doping material layer is formed in direct contact with the first electrode and the second electrode.

According to a preferred refinement of the invention, the first electrode is configured as a drain electrode, the second electrode is configured as a source electrode, a gate electrode is formed and a dielectric layer is formed between the channel layer and the gate electrode. This embodiment relates to a transistor, for example.

To improve the injection between the first and/or second electrode and the channel layer, the interface between the organic semiconductor material and the electrode and/or the electrodes may be doped. Alternatively, the interface may be improved by means of a thin dopant layer.

According to one embodiment, a doping material layer, which is not the channel layer and which contains or consists of the dopant material according to formula (I), is determined. The dopant material here functions as an electric n-dopant for the organic semiconducting material in the channel layer. Additional possible exemplary uses of the dopant material according to formula (I) are described in the following:

The doping material layer may consist exclusively of the dopant material according to formula (I). In this case, it forms a pure injection layer. The doping material layer may be arranged, for example, between the channel layer and at least one of the electrodes. It improves the exchange of charge carriers between the channel layer and at least one of the electrodes.

Alternatively, it is possible to provide that the doping material layer contains a matrix material and the dopant material according to formula (I). The doping material layer in this case forms a doped injection layer. The doping material layer may again be arranged between the channel layer and at least one of the electrodes, for example. It improves the exchange of charge carriers between the channel layer and at least one of the electrodes.

A region of the channel layer, which is doped with the dopant material, for example, and improves the exchange of the charge carriers between the remaining channel layer and at least one of the electrodes is referred to as the doped injection region. The doped injection region may be part of the channel layer but it may also be formed as an additional doped layer.

The invention may be embodied, for example, with the embodiments of the document US 2010/065833 A1. The organic semiconducting material of the channel layer and the dopant material according to formula (I) form a combination of materials in which electrical doping of the organic semiconductor material takes place when the two materials are combined in one layer. The electric doping here is based on a partial charge transfer between the two materials. In the component proposed in this embodiment of the invention, the organic semiconducting material is present in the so-called active layer and the dopant material according to formula (I) is arranged outside of the channel layer but is in direct contact with it, for example.

The arrangement of the dopant material according to formula (I) as a top layer (encapsulation layer) in direct contact with the channel layer results in the Fermi level of the channel layer, which is an active layer, being modified. This means that charge carriers are induced into the electrically undoped channel layer, which may also be referred to as quasi-doping. The induced charge carriers here preferably fill deep levels of the density-of-state distribution of the active layer and are only partially available as free charge carriers in the active layer or not at all. This has the advantage that the field effect mobility is increased by filling up imperfections without thereby creating additional imperfections. In addition, the proposed embodiment reduces both the starting voltage and the working voltage of the component, which is designed as an organic field effect transistor, for example.

According to a preferred refinement of the invention, the cover layer consists of an organic doping material. In an expedient embodiment of the invention, it is possible to provide that the dopant material according to formula (I) in the cover layer is incorporated into a matrix material for which the organic doping material is not an electric dopant.

Additionally or alternatively, the invention may be embodied with the embodiments of document US 2010/0051923 A1 in which the dopant material is not combined with the organic semiconducting material but instead is arranged as a very thin layer in an interfacial region between the active layer (channel layer) and the dielectric layer. Alternatively, the dopant material may be arranged adjacent to the interfacial region.

With the help of the very thin layer (so-called doping material layer which contains the dopant material), a quasi-doping takes place in the form of an electric doping, which is based on a partial charge transfer between the molecular doping material, on the one hand, and the organic material of the active layer, on the other hand, in the regions of the active layer adjacent to the doping material layer. Imperfections in the active layer, which result in charge carriers, namely electrons or holes, being captured there and then reducing the mobility of the charge carriers within the conducting channel are saturated during operation in the conducting channel. Saturated imperfections can no longer interfere with the flow of current in the conducting channel within the active layer. Unsaturated imperfections result in electrons or holes being captured, so that these charge carriers are repeatedly captured in imperfections and released again on their path through the conducting channel between a source electrode and a drain electrode. This negative effect is significantly reduced or even ruled out with this quasi-doping.

The doping material layer may be formed as a closed or a non-closed layer. The closed or non-closed layer, which may be formed by multiple separate subregions, for example, may be limited to a subsection of the interfacial region. The layer thickness of the doping material layer preferably amounts to at most one-tenth of the layer thickness of the active layer. A doping material layer with a thickness equal to or less than 5 nm is preferred.

The terms “energy of the HOMO” or E(HOMO) (HOMO—highest occupied molecular orbital) and “energy of the LUMO” and/or E(LUMO) (LUMO—lowest unoccupied molecular orbital) are usually synonymous with the terms ionization energy or electron affinity (Koopman's theorem). In n-doping, there is an electron transfer from the HOMO level of the n-dopant to the LUMO level of the matrix material, where the electron is not strongly localized but instead is counted with the charge carriers.

According to a refinement of the invention, the amount of a difference between the HOMO of the dopant material according to formula (I) and the LUMO of a matrix material of the channel layer is less than approximately 1 eV; more preferably, the amount of the difference is less than approximately 0.5 eV.

The organic semiconducting material of the channel layer may be an electron transporting material, for example. The material may have a high intrinsic charge carrier mobility, for example, greater than 10-4 cm2/Vs, preferably greater than or equal to 10-1 cm2/Vs. The organic semiconducting material preferably has a relatively low LUMO level of approximately 3 to 4.5 eV.

Examples of organic semiconducting matrix materials that can be used in the channel layer include: fullerene C60 and C70 and derivatives, e.g., PCMB, [6,6]-phenyl-C61-butyric acid methyl ester; pentacene and derivatives; rubrene; oligothiophenes and derivatives; phthalocyanine and metallophthalocyanine and derivatives, mainly fluorinated metalophthalocyanines; PTCDI, perylene tetracarboxylic diimide and derivatives, polymers, e.g., P3HT.

The layers can be produced, for example, by vacuum evaporation, for example, by VTE (vacuum thermal evaporation) or OVPD (organic vapor phase deposition). In addition, vacuum spray methods may also be used for production. Another example of a type of deposition includes thermally or optically induced transfer of the material from a carrier substrate to the actual substrate, for example, by means of LITI (laser induced thermal imaging). Alternatively or additionally, pressure methods such as stamping, embossing and/or stamp transfer may also be used. Doped layers are produced in vacuo, typically by means of mixed evaporation from two independently regulated sources for the matrix material and the dopant. Alternatively, they may also be formed by interdiffusion from a dopant layer into a matrix material layer situated beneath it, wherein the two materials are vapor-deposited one after the other in vacuo and then interdiffusion is facilitated thermally or by means of solvents. Under some circumstances, the dopant may be activated in the layer during or after the production process in the layer through suitable physical and/or chemical measures, for example, by the action of light or the action of magnetic and/or electric fields.

Alternative production methods for the doped layers include:
Doping a matrix layer by a solution of dopants with subsequent evaporation of the solvent, in particular by thermal treatment.
Surface doping of a matrix material layer by a layer of dopants applied superficially.
Production of a solution of matrix molecules and dopants and then production of a layer of the solution by means of conventional methods, for example, evaporation of the solvent or by spin-coating.

Alternatively, the doping may also be performed by evaporating the dopant from a precursor compound, which releases the dopant material when heated and/or irradiated. It is self-evident that the dopant material may also be released in the matrix.

### BRIEF DESCRIPTION OF THE DRAWINGS

The invention is explained in greater detail below on the basis of preferred exemplary embodiments with reference to the figures of a drawing, in which:

FIG. 1 shows a schematic diagram of the structure of a planar component,

FIG. 2 shows a schematic diagram of the structure of an additional planar component,

FIG. 3 shows a schematic diagram of the structure of yet another planar component,

FIG. 4 shows a schematic diagram of the structure of an exemplary planar component,

FIG. 5 shows a schematic diagram of the structure of an additional exemplary planar component, and

FIG. 6 shows a schematic diagram of the structure of yet another exemplary planar component.

### DETAILED DESCRIPTION

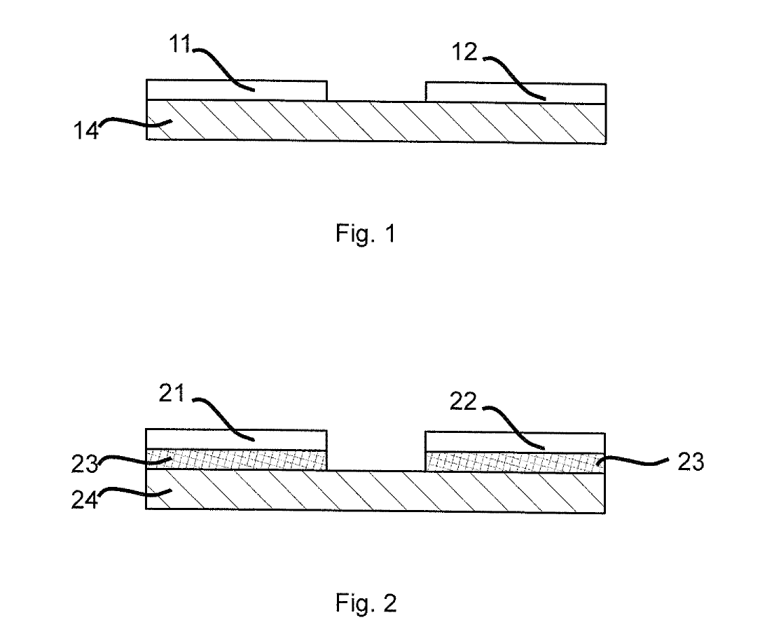

FIG. 1 shows a schematic diagram of the structure of a planar component with a first electrode 11, a second electrode 12 and a channel layer 14.

FIG. 2 shows a schematic diagram of another planar component with a first electrode 21, a second electrode 22 and a channel layer 24. An injection layer 23 is arranged between the first and second electrodes 21, 22 and a channel 24. The injection layers may contain the dopant material.

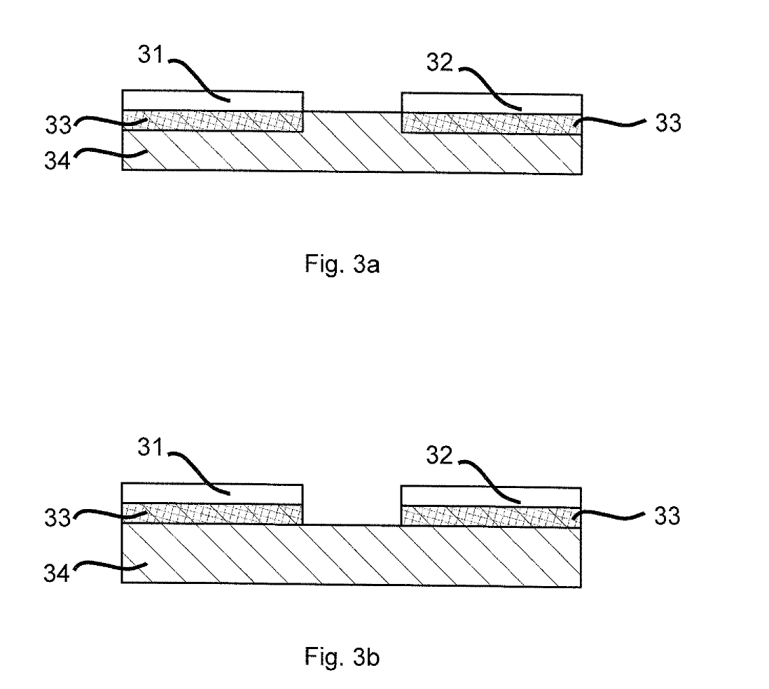

FIG. 3 shows a schematic diagram of the structure of yet another planar component. The component comprises a first electrode 31, a second electrode 32 and a channel layer 34. Injection regions 33 are formed adjacent to the first and second electrodes 31, 32. The injection regions 33 may be doped with the dopant material. The injection regions 33 in FIG. 3a are formed as part of the channel layer 34. FIG. 3b shows an embodiment, in which the injection regions 33 are formed as an additional doped layer between the channel layer 34 and the first and second electrodes 31, 32. The additional layer comprises a semiconductor material as the matrix material and the dopant material according to formula (I). The additional layer and the channel layer here may comprise the same semiconductor material.

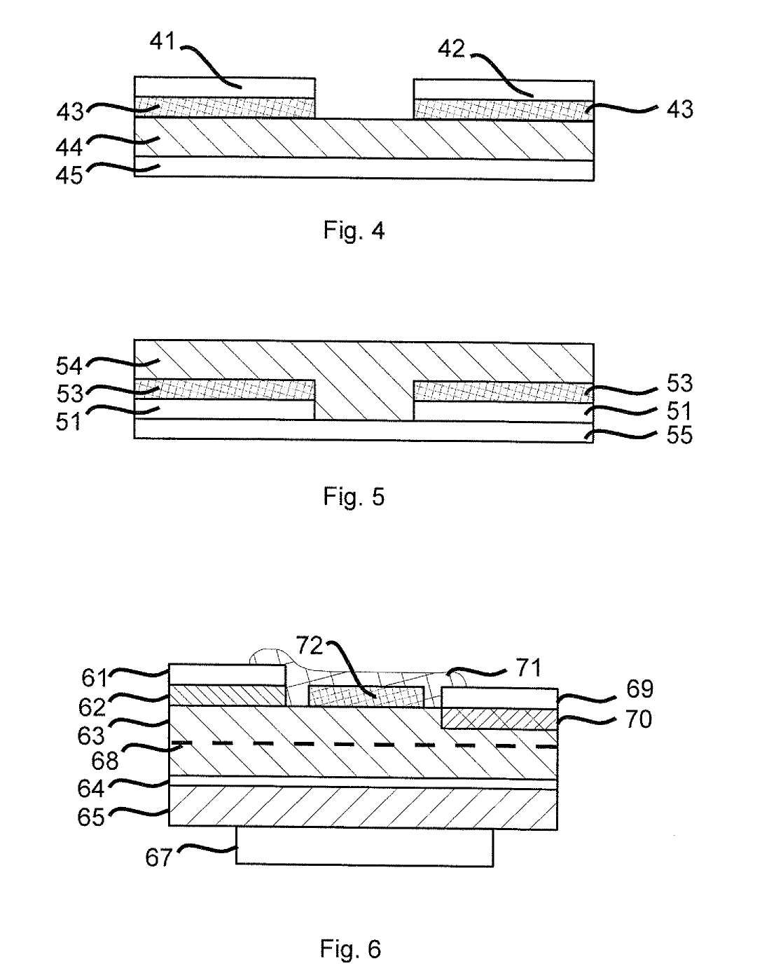

FIG. 4 shows a schematic diagram of the structure of a planar component having a first electrode 41 and a second electrode 42 as well as a channel layer 44. Doped injection regions 43 are again formed on the first and second electrodes 41, 42. The channel layer 44, the injection regions 43 as well as the first and second electrodes are arranged on a substrate 45.

FIG. 5 shows an alternative schematic diagram of the structure of a planar component. The component comprises a first electrode 51, a second electrode 52, a channel layer 54 and the doped injection regions 53. The aforementioned components are arranged on a substrate 55.

FIG. 6 shows another alternative schematic diagram of the structure of a planar component. The component comprises a first electrode 61 and a second electrode 69 as well as a substrate 67. FIG. 6 in particular shows in which regions of the component the dopant material can be used. The dopant material may be used, for example, in an injection layer 62, in a doped injection region 70, in a cover layer 72, as a thin break-through channel layer 68 and/or as a thin break-through layer 64 between a gate insulator 65 and a channel layer 63. Additionally or alternatively, the dopant material may be used in an unstructured injection layer, which extends continuously between a source electrode and a semiconductor, over the channel layer and between a drain electrode and the semiconductor (extension of layer 62 not shown) and is compensated via the channel layer (between the source and the drain electrodes) by a layer 72. The dopant material can also be used in the layer 71 to compensate for another dopant, for example, a p-dopant.

The following table shows preferred exemplary compounds for the dopant material according to formula (I).

| | |
|---|---|
| 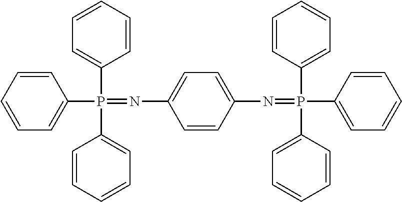 [SMILES: c1ccc(P(=Nc2ccc(N=P(c3ccccc3)(c3ccccc3)c3ccccc3)cc2)(c2ccccc2)c2ccccc2)cc1] | 1 |
| 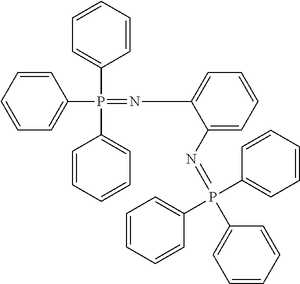 [SMILES: c1ccc(P(=Nc2ccccc2N=P(c2ccccc2)(c2ccccc2)c2ccccc2)(c2ccccc2)c2ccccc2)cc1] | 2 |
| 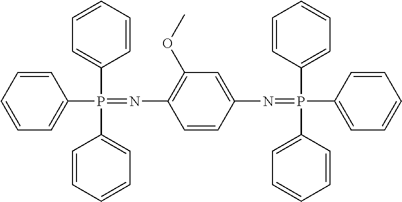 [SMILES: COc1cc(N=P(c2ccccc2)(c2ccccc2)c2ccccc2)ccc1N=P(c1ccccc1)(c1ccccc1)c1ccccc1] | 3 |
| 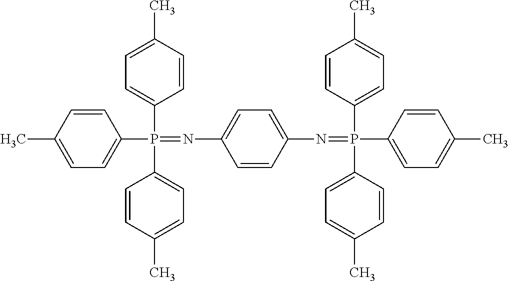 | 4 |
| 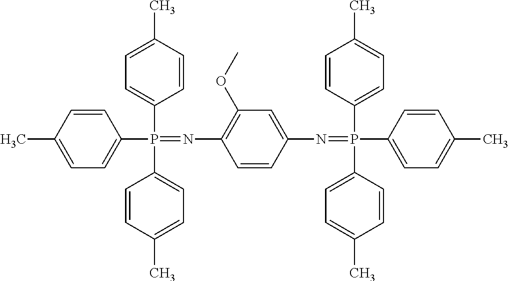 | 5 |
| 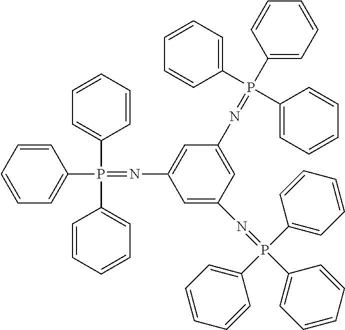 [SMILES: c1ccc(P(=Nc2cc(N=P(c3ccccc3)(c3ccccc3)c3ccccc3)cc(N=P(c3ccccc3)(c3ccccc3)c3ccccc3)c2)(c2ccccc2)c2ccccc2)cc1] | 6 |
| 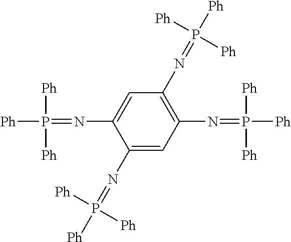 [SMILES: c1ccc(P(=Nc2cc(N=P(c3ccccc3)(c3ccccc3)c3ccccc3)c(N=P(c3ccccc3)(c3ccccc3)c3ccccc3)cc2N=P(c2ccccc2)(c2ccccc2)c2ccccc2)(c2ccccc2)c2ccccc2)cc1] | 7 |
| 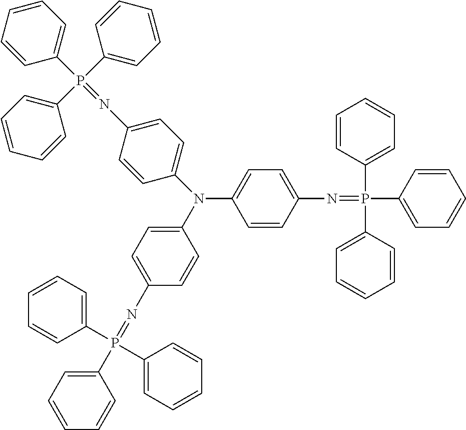 [SMILES: c1ccc(P(=Nc2ccc(N(c3ccc(N=P(c4ccccc4)(c4ccccc4)c4ccccc4)cc3)c3ccc(N=P(c4ccccc4)(c4ccccc4)c4ccccc4)cc3)cc2)(c2ccccc2)c2ccccc2)cc1] | 8 |
| 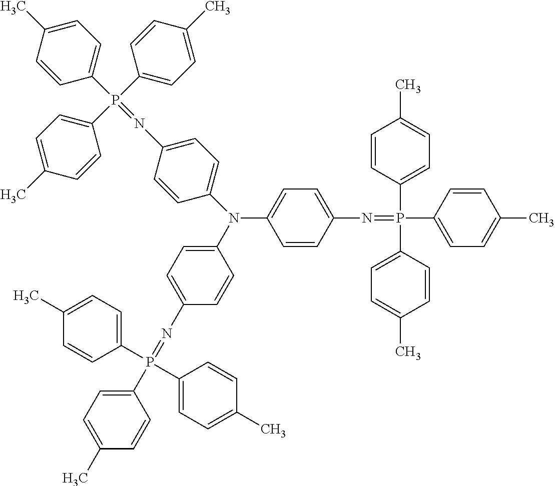 | 9 |
| 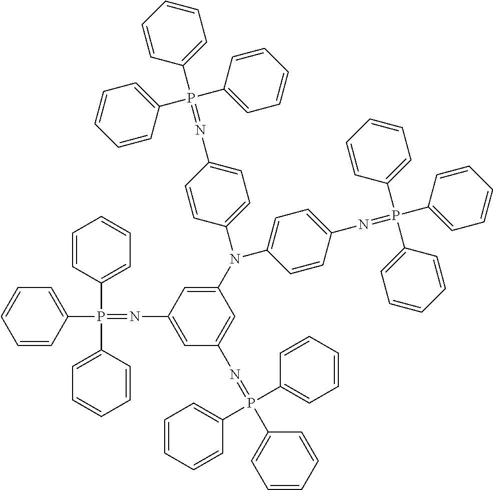 [SMILES: c1ccc(P(=Nc2ccc(N(c3ccc(N=P(c4ccccc4)(c4ccccc4)c4ccccc4)cc3)c3cc(N=P(c4ccccc4)(c4ccccc4)c4ccccc4)cc(N=P(c4ccccc4)(c4ccccc4)c4ccccc4)c3)cc2)(c2ccccc2)c2ccccc2)cc1] | 10 |
| 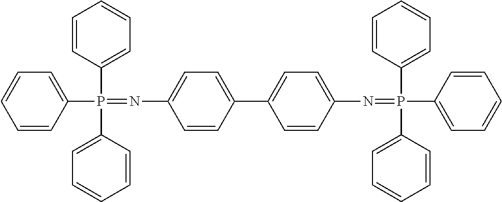 [SMILES: c1ccc(P(=Nc2ccc(-c3ccc(N=P(c4ccccc4)(c4ccccc4)c4ccccc4)cc3)cc2)(c2ccccc2)c2ccccc2)cc1] | 11 |
| 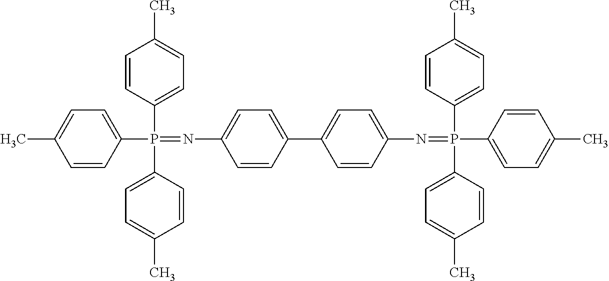 | 12 |
| 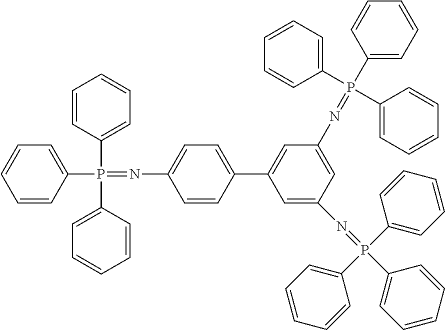 [SMILES: c1ccc(P(=Nc2ccc(-c3cc(N=P(c4ccccc4)(c4ccccc4)c4ccccc4)cc(N=P(c4ccccc4)(c4ccccc4)c4ccccc4)c3)cc2)(c2ccccc2)c2ccccc2)cc1] | 13 |
| 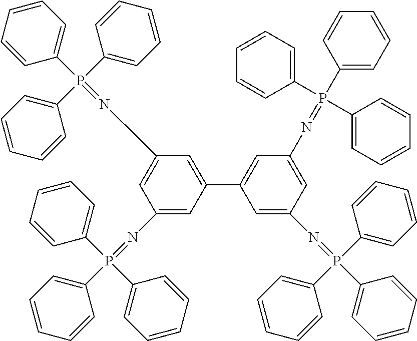 [SMILES: c1ccc(P(=Nc2cc(N=P(c3ccccc3)(c3ccccc3)c3ccccc3)cc(-c3cc(N=P(c4ccccc4)(c4ccccc4)c4ccccc4)cc(N=P(c4ccccc4)(c4ccccc4)c4ccccc4)c3)c2)(c2ccccc2)c2ccccc2)cc1] | 14 |
| 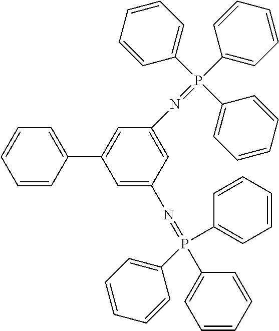 [SMILES: c1ccc(-c2cc(N=P(c3ccccc3)(c3ccccc3)c3ccccc3)cc(N=P(c3ccccc3)(c3ccccc3)c3ccccc3)c2)cc1] | 15 |
| 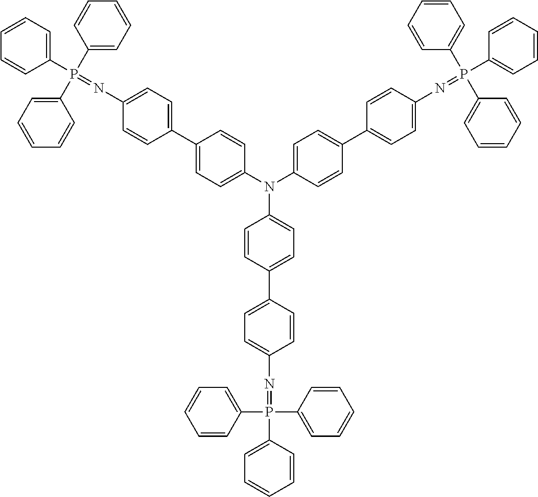 [SMILES: c1ccc(P(=Nc2ccc(-c3ccc(N(c4ccc(-c5ccc(N=P(c6ccccc6)(c6ccccc6)c6ccccc6)cc5)cc4)c4ccc(-c5ccc(N=P(c6ccccc6)(c6ccccc6)c6ccccc6)cc5)cc4)cc3)cc2)(c2ccccc2)c2ccccc2)cc1] | 16 |
| 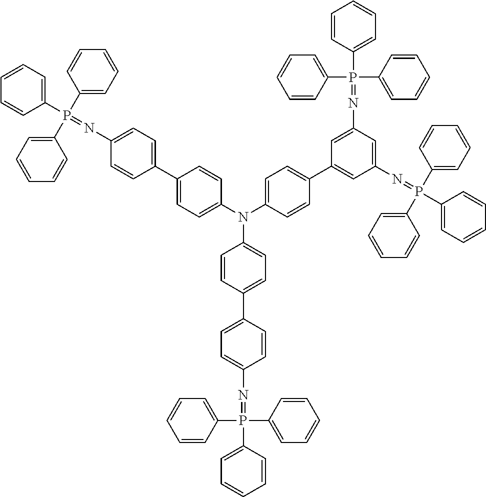 [SMILES: c1ccc(P(=Nc2ccc(-c3ccc(N(c4ccc(-c5ccc(N=P(c6ccccc6)(c6ccccc6)c6ccccc6)cc5)cc4)c4ccc(-c5cc(N=P(c6ccccc6)(c6ccccc6)c6ccccc6)cc(N=P(c6ccccc6)(c6ccccc6)c6ccccc6)c5)cc4)cc3)cc2)(c2ccccc2)c2ccccc2)cc1] | 17 |
| 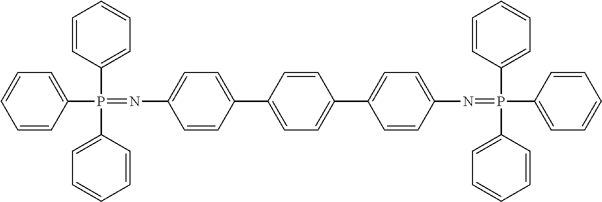 [SMILES: c1ccc(P(=Nc2ccc(-c3ccc(-c4ccc(N=P(c5ccccc5)(c5ccccc5)c5ccccc5)cc4)cc3)cc2)(c2ccccc2)c2ccccc2)cc1] | 18 |
| 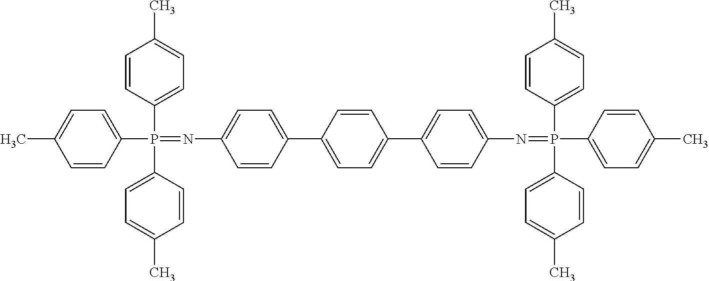 | 19 |
| 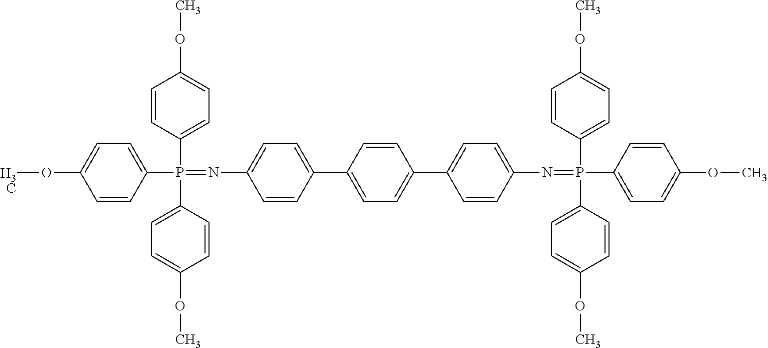 | 20 |
| 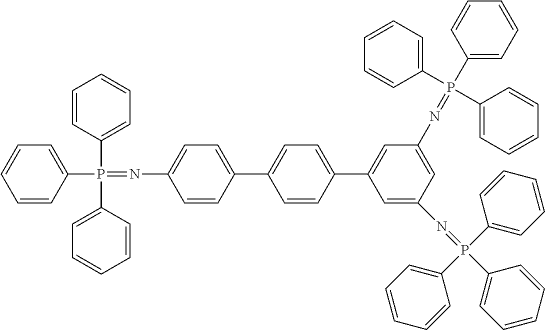 [SMILES: c1ccc(P(=Nc2ccc(-c3ccc(-c4cc(N=P(c5ccccc5)(c5ccccc5)c5ccccc5)cc(N=P(c5ccccc5)(c5ccccc5)c5ccccc5)c4)cc3)cc2)(c2ccccc2)c2ccccc2)cc1] | 21 |
| 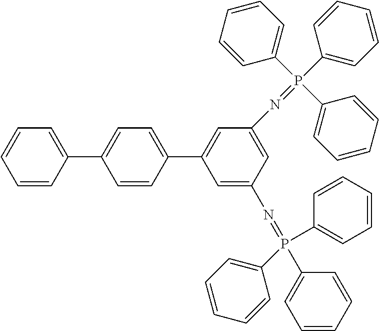 [SMILES: c1ccc(-c2ccc(-c3cc(N=P(c4ccccc4)(c4ccccc4)c4ccccc4)cc(N=P(c4ccccc4)(c4ccccc4)c4ccccc4)c3)cc2)cc1] | 22 |
| 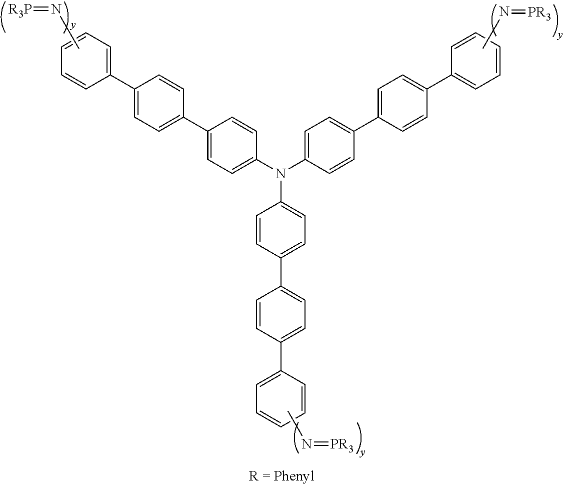 | 23 |
| 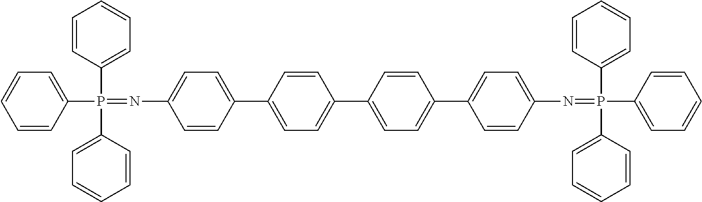 [SMILES: c1ccc(P(=Nc2ccc(-c3ccc(-c4ccc(-c5ccc(N=P(c6ccccc6)(c6ccccc6)c6ccccc6)cc5)cc4)cc3)cc2)(c2ccccc2)c2ccccc2)cc1] | 24 |
| 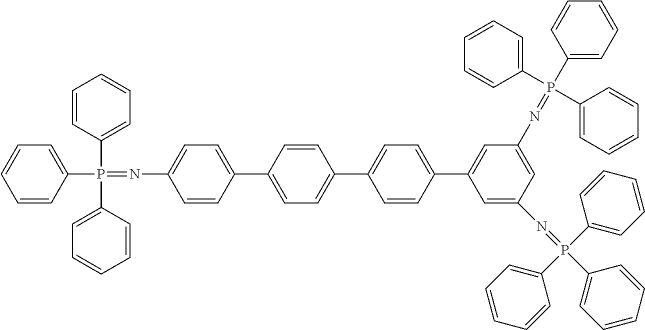 [SMILES: c1ccc(P(=Nc2ccc(-c3ccc(-c4ccc(-c5cc(N=P(c6ccccc6)(c6ccccc6)c6ccccc6)cc(N=P(c6ccccc6)(c6ccccc6)c6ccccc6)c5)cc4)cc3)cc2)(c2ccccc2)c2ccccc2)cc1] | 25 |

Additional details regarding a few exemplary compounds are disclosed below.

### Compound 1

### 1,4-bis(triphenylphosphinimine)-benzene

12.30 g (37.0 mmol) triphenylphosphine dichloride were dissolved in 80 mL benzene, then 10 mL triethylamine and 2.0 g (18.5 mmol) 1,4-phenylenediamine were added and the mixture was heated for two days at reflux. After cooling, the suspension was filtered and the precipitant was washed with a dilute sodium hydroxide solution, followed by ethanol/water. After drying in vacuo, 9.20 g (14.6 mmol; 79%) was obtained as a yellow solid. The substance was purified by gradient sublimation for characterization.

Melting point (DSC): 272° C.

### Compound 2

### 1,2-bis(triphenylphosphinimine)-benzene

10.0 g (30.0 mmol) triphenylphosphine dichloride was dissolved in 100 mL toluene, then 8.5 mL triethylamine and 1.62 g (15.0 mmol) 1,2-phenylenediamine were added and the mixture was heated for two days at 95° C. After cooling, the suspension was filtered, and the precipitate was washed with toluene. The residue was suspended in a 2-molar sodium hydroxide solution and stirred for 5 minutes at 45° C. After filling and drying in vacuo, 4.73 g (7.53 mmol; 50%) light yellow solids were obtained. The substance was purified by gradient sublimation for characterization.

Melting point (DSC): 257° C.

CV (DCM): 0.29 V vs. Fc

### Compound 3

### 1,4-bis(triphenylphosphinimine)-2-methoxybenzene

### Step 1: Reduction of 2-methoxy-4-nitroaniline

3.0 g (17.8 mmol) 2-methoxy-4-nitroaniline and 0.8 g palladium on activated carbon (10%) were added to 100 mL tetrahydrofuran. Then 8.7 mL (114.0 mmol) hydrazine-monohydrate was added cautiously to 40 mL tetrahydrofuran and the reaction was stirred for 3 hours at 90° C. After cooling, the suspension was filtered and the precipitate was washed with tetrahydrofuran. The mother liquor was concentrated under a reduced pressure to form a gray residue; 2.44 g (17.7 mmol, 99%) of the product was stored under argon and used without further purification.

### Step 2: 1,4-bis(triphenylphosphinimine)-2-methoxybenzene

3.71 g (11.2 mmol) triphenylphosphine dichloride was dissolved in 50 mL toluene under argon. A suspension of 3.1 mL (22.3 mmol) triethylamine and 0.77 g (5.6 mmol) 2-methoxy-1,4-phenylenediamine in 50 mL toluene was added and the mixture was heated for two days at 95° C. After cooling, the suspension was filtered and the precipitate was washed with toluene and then suspended in a 2-molar sodium hydroxide solution and stirred for 5 minutes at 45° C., then filtered and washed with water. After drying in vacuo, 1.96 g (2.98 mmol; 53%) brown solid was obtained.

Melting point (DSC): 206° C.

CV (DCM): −0.45 V vs. Fc (rev)

### Compound 4

### 1,4-bis(tritolylphosphinimine)benzene

### Step 1: Synthesis of tris(4-methylphenyl)phosphine dichloride

11.7 g (49.3 mmol) hexachloroethane was added to a suspension of 15.0 g (49.3 mmol) tris(4-methylphenyl)phosphine in 80 mL acetonitrile under argon. The mixture was stirred for 17 hours at 95° C. After cooling, 200 mL dry toluene was added and 50 mL acetonitrile was removed under a reduced pressure. The precipitate was filtered and washed with 50 mL dry toluene and 50 mL dry hexane; after drying in vacuo, 9.83 g (53%) white solid was obtained.

### Step 2: 1,4-bis(tritoluoylphosphinimine)-benzene

A solution of 5.8 mL (41.6 mmol) triethylamine in 10 mL dry toluene was to a mixture of 7.81 g (20.8 mmol) tris(4-methylphenyl)phosphine dichloride at 5° C. under an argon atmosphere, then 1.12 g (10.4 mmol) 1,4-phenylenediamine was added. The mixture was stirred for 1 hour at 110° C. The yellow precipitate was filtered out and washed with toluene and hexane. The dry raw product was suspended in 2-molar sodium hydroxide solution and stirred for 5 minutes at 45° C. After filtering, washing with water and drying in vacuo, 5.43 g (7.6 mmol; 73.3%) light yellow solid was obtained. The substance was purified by gradient sublimation for characterization.

Melting point (DSC): 267° C.

CV (DCM): −0.46 V vs. Fc (rev)

### Compound 5

### 1,4-bis(tritoluoylphosphinimine)-2-methoxybenzene

### Step 1: Synthesis of tritoluoylphosphine dichloride

See above

### Step 2: Reduction of 2-methoxy-4-nitroaniline

See above

### Step 3: 1,4-bis(tritoluoylphosphinimin)-2-methoxybenzene

2.0 g (5.33 mmol) tritoluoylphosphine dichloride was dissolved in 10 mL toluene under argon. A suspension of 1.5 mL (10.7 mmol) triethylamine and 0.37 g (2.7 mmol) 2-methoxy-1,4-phenylenediamine in 15 mL toluene was added and the mixture was heated for 18 hours at 90° C. After cooling, the suspension was filtered and the precipitate was washed with toluene and then suspended in a 2-molar sodium hydroxide solution and stirred for 5 minutes at 45° C., then filtered and washed with water. After drying in vacuo, 0.43 g (0.59 mmol; 22%) yellow solid was obtained.

Melting point (DSC): 239° C.

CV (DCM): −0.51 V vs. Fc

### Compound 7

### 1,2,4,5-tetra(triphenylphosphinimine)benzene

4.9 mL (35.2 mmol) triethylamine and 0.5 g (1.78 mmol) 1,2,4,5-tetraminobenzene tetrahydrochloride were suspended in 20 mL acetonitrile, then 2.93 g (8.8 mmol) triphenylphosphine dichloride was dissolved in 15 mL acetonitrile and added to the suspension at 0° C. The mixture was stirred for 18 hours at room temperature period. The suspension was filtered and the precipitate was suspended in 2-molar sodium hydroxide solution and stirred for 5 minutes at 45° C. After filtering and drying in vacuo, 0.74 g (0.6 mmol; 35%) reddish-brown solids were obtained.

Melting point (DSC): 283° C.

CV (DCM)=−1.02 V vs. Fc (rev.)

### Compound 8

### tris(4-triphenylphospiniminphenyl)amine

1.72 g (5.44 mmol) triphenylphosphine dichloride was dissolved in 8 mL dichloromethane under an argon atmosphere, then 1.8 mL (12.9 mmol) triethylamine in 2 mL dichloromethane was added slowly to the solution, then 0.5 g (1.7 mmol) tris(4-aminophenyl)amine was added and the mixture was stirred for 4 days at room temperature. The reaction [mixture] was diluted with dichloromethane and extracted with water. Under reduced pressure the organic phase was concentrated. The precipitate was suspended in a 2-molar sodium hydroxide solution and stirred for 5 minutes at 45° C. After filtration and drying in vacuo, 1.50 g (1.40 mmol; 82%) solids were obtained.

Melting point (DSC): 277° C.

CV (DMF): −0.39 V vs. Fc.

### Compound 9

### tris(4-tristoluoylphospiniminephenyl)amine

### Step 1: Synthesis of tritoluoylphosphine dichloride

See above

### Step 2: tris(4-tristoluoylphospiniminphenyl)amine

A solution of 3.8 mL (27.4 mmol) triethylamine in 10 mL dry toluene was added at 5° C. under an argon atmosphere to a mixture of 3.82 g (10.2 mmol) tris(4-methylphenyl)phosphine dichloride in 40 mL toluene, then 1.0 g (3.4 mmol) tris(4-aminophenyl)amine was added. The mixture was stirred for a hour at 110° C. The precipitate was filtered and washed with toluene and hexane. The dry raw product was suspended in 2-molar setting hydroxide solution and stirred for 5 minutes at 45° C. After filtering and drying in vacuo, 3.06 g (2.6 mmol; 75%) light-yellow solids were obtained.

### Compound 11

### 4,4′-bis(triphenylphosphinimine)-1,1′-biphenyl

4.15 g (12.5 mmol) triphenylphosphine dichloride was dissolved in 30 mL benzene, then 3.4 mL triethylamine and 1.15 g (6.25 mmol) benzidine were added. The mixture was stirred at reflux for 3 hours. After cooling, this suspension was filtered and the yellow precipitate was washed with dilute sodium hydroxide solution, followed by ethanol/water. After drying in vacuo, 3.20 g (4.66 mmol; 73%) yellow solids were obtained. The substance was purified by gradient sublimation to characterize it.

Melting point (DSC): 283° C.

CV (DCM): 0.0 V vs. Fc (rev.)

### Compound 18

### 4,4″-bis(triphenylphosphinimine)-p-terphenyl

2.50 g (7.5 mmol) triphenylphosphine dichloride was dissolved in 50 mL toluene, then 2.9 mL triethylamine and 0.88 g (3.4 mmol) 4,4″-diamino-p-terphenyl were added and the mixture was stirred for 2 days at 95° C. After cooling, the suspension was filtered and the yellow precipitate was washed with dilute sodium hydroxide solution, followed by water and acetonitrile, yielding 2.06 g (2.6 mmol; 78%) light-yellow solids after drying in vacuo. The substance was purified by gradient sublimation to characterize it.

Melting point (DSC): 322° C.

CV (DCM): 0.22 V vs. Fc (rev)

### Compound 19

### N4,N4″-bis(tri-p-tolylphosphoranylidene)-[1,1′:4′,1″-terphenyl]-4,4″-diamine

### Step 1: Synthesis of tritolylphosphine dichloride

11.7 g (49.3 mmol) hexachloroethane was added to a suspension of 15.0 g (49.3 mmol) tris(4-methylphenyl)phosphine in 80 mL acetonitrile under an argon atmosphere. The mixture was stirred for 17 hours at 95° C. After cooling, 200 mL dry toluene was added and 50 mL acetonitrile was removed under reduced pressure. The precipitate was filtered and washed with 50 mL dry toluene and 50 mL dry hexane, yielding 9.83 g (53%) of a white solid substance after drying in a high vacuum.

### Step 2: Synthesis of N4,N4″-bis(tri-p-tolylphosphoranylidene)-[1,1′:4′,1″-terphenyl]-4,4″-diamine

1.69 g (4.5 mmol) [of what?] in 3.3 mL dichloromethane was added to a solution of 0.52 g (2 mmol) tritolylphosphine dichloride in 5 mL toluene. The mixture was stirred at reflux for 3 hours after adding 1 g (10 mmol) triethylamine. The precipitate was filtered, dried and suspended in 2-molar sodium hydroxide solution, stirred for 5 minutes at 45° C., then 0.93 g (1.1 mmol; 55%) of a brown solid substance was obtained after filtering, washing with water and drying in vacuo. The substance was purified by gradient sublimation to characterize it.

Melting point: 314° C.

CV (DCM): 0.18 V vs. Fc

### Compound 20

### N4,N4″-bis(tris(4-methoxyphenyl)phosphoranylidene)-[1,1′:4′,1″-terphenyl]-4,4″-diamine

### Step 1: Synthesis of 4,4″-diazide-1,1′:4′,1″-terphenyl

0.63 g (9.3 mmol) sodium nitrite in 5 mL water in 0.56 g (9.3 mmol) urea in 5 mL water were added to a mixture of 1.2 g (4.5 mmol) [1,1′:4′,1″-terphenyl]-4,4″-diamine, 7.5 mL silicic acid and 3.3 mL sulfuric acid at 0° C. After stirring for 1 hour, 0.64 g (9.8 mmol) sodium azide in 5 mL water was added slowly. The mixture was stirred for 3 hours at room temperature and then poured onto ice. The precipitate was filtered, washed with water and dried in vacuo, yielding 1.3 g (4.2 mmol, 93%) brown solids that were used without further purification.

### Step 2: N4,N4″-bis(tris(4-methoxyphenyl)phosphoranylidene)-[1,1′:4′,1″-terphenyl]-4,4″-diamine

To a solution of 0.66 g (2.1 mmol) 4,4″-diazide-1,1′:4′,1″-terphenyl in 15 mL toluene, we added 1.48 g (4.2 mmol) tris(4-methoxyphenyl)phosphine in 5 mL toluene under an argon atmosphere. After 18 hours of stirring at room temperature, the solvent was distilled off and the residue was washed with toluene, yielding 1.70 g (1.8 mmol) yellow powder after drying in vacuo.

Melting point: 328° C.

### Compound 28

### N1,N4-bis(tricyclohexylphosphoranylidene)benzene-1,4-diamine

8.1 g (34.2 mmol) hexachloroethane was added to a suspension of 9.6 g (34.2 mmol) tricyclohexylphosphine in 60 mL acetonitrile under an argon atmosphere. The mixture was stirred for 16 hours at 95° C. After cooling to room temperature, a solution of 1.7 g (15.5 mmol) para-phenylenediamine and 11.5 mL (77.5 mmol) 2,3,4,6,7,8,9,10-octahydro-pyrimidone[1,2-a]azepine in 25 mL acetonitrile was added. The mixture was stirred for 16 hours at 95° C. and then cooled again to room temperature. The precipitate was filtered, dried and suspended in 2-molar sodium hydroxide solution and stirred for 5 minutes at 45° C., then 5 g (7.5 mmol; 49%) of a brown solid was obtained after filtering, washing with water and drying in vacuo. The substance was purified by gradient sublimation to characterize it.

Melting point: 277° C.

CV (THF): −0.07 V vs. Fc

### Compound 29

### N1,N4-bis(dimethylaminophosphoranylidene)benzene-1,4-diamine

8.1 g (34.2 mmol) hexachloroethane was added to a suspension of 9.6 g (34.2 mmol) tricyclohexylphosphine in 75 mL acetonitrile under an argon atmosphere. The mixture was stirred for 16 hours at 95° C. After cooling to room temperature, a solution of 3 g (27.7 mmol) para-phenylenediamine and 20.6 mL (138.5 mmol) 2,3,4,6,7,8,9,10-octahydropyramidone[1,2-a]azepine in 15 mL acetonitrile was added. The mixture was stirred for 16 hours at 95° C. and then cooled again to room temperature the solvent was distilled down to 20 mL. The precipitate was filtered, dried and suspended in 2-molar sodium hydroxide solution and stirred for 5 minutes at 45° C. Leaching out with toluene and washing with ethyl acetate as well as drying in vacuo yielded 1.2 g (2.8 mmol; 10%) of a brown solid substance. The substance was purified by means of gradient sublimation to characterize it.

Melting point: 127° C.

CV (DCM): −0.61 V vs. Fc

### Compound 30

### N1,N5-bis(triphenylphosphoranylidene)naphthalene-1,5-diamine

4.17 g (12.5 mmol) triphenylphosphine dichloride was dissolved in 30 mL benzene, then 3.4 mL triethylamine and 1.0 g (6.25 mmol) naphthalene-1,5-diamine were added and the mixture was heated for 3 days at 80° C. After cooling, the suspension was filtered and the residue was suspended in 2-molar sodium hydroxide solution and stirred for 5 minutes at 45° C., yielding 2.18 g (3.21 mmol; 51%) of a yellow solid substance after filtering and drying in vacuo. The substance was purified by means of gradient sublimation to characterize it.

Melting point: 257° C.

CV (DCM): 0.26 V vs. Fc

### Compound 31

### N1,N4-bis(methyldiphenylphosphoranylidene)benzene-1,4-diamine

4.7 g (20 mmol) hexachloroethane was added to a suspension of 4 g′ (20 mmol) methyldiphenylphosphine in 25 mL acetonitrile under an argon atmosphere. The mixture was stirred for 2.5 hours at 95° C. After cooling to room temperature, a solution of 0.98 g (9.1 mmol) para-phenylenediamine and 6.3 mL (45.5 mmol) 2,3,4,6,7,8,9,10-octahydropyramidone[1,2-a]azepine in 10 mL acetonitrile was added. The mixture was stirred for 16 hours at 95° C. and then cooled again to room temperature. The precipitate was filtered, dried and suspended in 2-molar sodium hydroxide solution and stirred for 5 minutes at 45° C., yielding 1.2 g (2.4 mmol; 26%) of a brown solid substance after filtering, washing with water and drying in vacuo. The substance was purified by means of gradient sublimation to characterize it.

Melting point: 225° C.

CV (DCM): −0.23 V vs. Fc

The intensity of the doping was determined by means of conductivity measurements. The conductivity of a thin-film specimen can be measured by the so-called two-point method, in which contacts of a conductive material, for example, gold or indium tin oxide, are applied to a substrate. Then the thin film to be investigated is applied to the substrate over a large area, so that the contacts are covered by the thin film. This structure corresponds to that of a resistor. After applying a voltage to the contacts, the current flowing through them is measured. The resistance and/or the conductivity of the thin-film material can be determined from the geometry of the contacts and the layer thickness of the applied thin film.

Multiple OTFTs were produced on SiO2 substrates. To produce an OTFT, an Al gate electrode and a gate dielectric were arranged on the substrate. The gate dielectric may be made of 3.6 nm aluminum oxide and 1.7 nm tetradecylphosphonium acid, for example (Zschieschang, Adv. Mater, v. 22, pp. 982 (2010)). Then a layer of F16CuPc with a thickness of 30 nm was arranged thereon as a semiconductor layer. The source and drain injection layers were deposited on the semiconductor layer. Using the same mask, a source electrode and a drain electrode of gold were then applied, forming an n-doped channel layer more than 1 μm wide.

The multiple OTFTs were produced using various channel layer widths, so that the contact resistance can be determined by extrapolation. The contact resistance is 9 kOhm·cm for injection layers with a thickness of 2.5 nm, and 17 kOhm·cm for injection layers with a thickness of 5 nm. A comparative example without doping had a contact resistance of 48 kOhm·cm.

It has surprisingly been found that not only the dopant material but also the components produced with it are stable in air. After 50 days under a normal atmosphere, i.e., exposed to air and ambient oxygen, the contact resistance had increased to 22 kOhm·cm. This is a slight increase in comparison with the undoped component. A comparative example with the other stronger n-dopant resulted in an initial contact resistance of 7 kOhm·cm. After 50 days under a normal atmosphere, however, the contact resistance was already 30 kOhm·cm.

Features of the present invention disclosed in the preceding description, the claims and the drawings may be important either individually or in any combination for the implementation of the invention in its various embodiments.

1. An organic electronic component comprising;
a first electrode,
a second electrode,
a channel layer comprising an organic semiconducting material, and
a dopant material according to formula A-B,
wherein 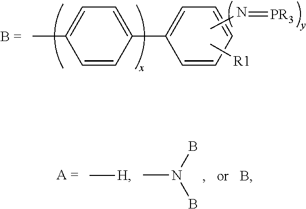
and
wherein R1, R, x, and y are independently selected from the following groups:
x is 0, 1, or 2;
y is 1, 2, 3, or 4;
R is an aryl group; and
R1 is an alkyl group or the alkoxy group.

2. The organic electronic component according to claim 1, wherein the dopant material is incorporated into a doping material layer.

3. The organic electronic component according to claim 2, wherein the doping material layer consists of the dopant material.

4. The organic electronic component according to claim 2, wherein the doping material layer is arranged on the organic semiconducting material.

5. The organic electronic component according to claim 1, wherein the dopant material is incorporated into the organic semiconducting material.

6. The organic electronic component according to claim 1, wherein the absolute amount of the difference between the oxidation potential of the dopant material and the reduction potential of the organic semiconducting material is greater than about 0.5 V.

7. The organic electronic component according to claim 2, wherein the doping material layer comprises multiple layers, including a first partial layer and a second partial layer, wherein the first partial layer consists of the dopant material, the second partial layer consists of a charge carrier-transporting matrix material and the second partial layer is arranged between the first partial layer and the channel layer and is in contact with the first partial layer and the channel layer.

8. The organic electronic component according to claim 1, wherein the organic semiconducting material is an electron-conducting material.

9. The organic electronic component according to claim 2, wherein the doping material layer is in direct contact with the first electrode and the second electrode.

10. The organic electronic component according to claim 1, wherein
the first electrode is configured as a drain electrode,
the second electrode is configured as a source electrode, and
the component further comprises a gate electrode and
a dielectric layer, wherein the dielectric layer is arranged between the channel layer and the gate electrode.
